(19) United States
(12) Patent Application Publication
(10) Pub. No.: US 2024/0178106 A1
(43) Pub. Date: May 30, 2024

(54) LEAD FRAME APPARATUS, SEMICONDUCTOR DEVICE AND METHOD OF MAKING A SEMICONDUCTOR DEVICE

(71) Applicant: TEXAS INSTRUMENTS INCORPORATED, DALLAS, TX (US)

(72) Inventor: Daniel Harold MATEO, IRVING, TX (US)

(21) Appl. No.: 18/060,239

(22) Filed: Nov. 30, 2022

(51) Int. Cl. H01L 23/495; H01L 21/48; H01L 21/56; H01L 23/31

(52) U.S. Cl. CPC H01L 23/49544; H01L 21/4825; H01L 21/4842; H01L 21/565; H01L 23/3107; H01L 23/49503; H01L 23/4952

(57) ABSTRACT

A lead frame sheet can include a plurality of lead frames and a reinforcement feature. A pair of adjacent lead frames includes an arrangement of opposing leads along adjacent edges thereof, in which the opposing leads are spaced apart from and coupled to each other by an elongated dam bar. The dam bar extends longitudinally along the adjacent edges of the adjacent lead frames. The reinforcement feature extends across the dam bar, in which the leads and the reinforcement feature have a thickness, in a direction orthogonal to a surface of the sheet, which is greater than a thickness of the dam bar.

### TECHNICAL FIELD

This description relates generally to a lead frame apparatus, semiconductor device and to methods of making a semiconductor device.

### BACKGROUND

The backend fabrication process for semiconductor devices includes placing semiconductor die on lead frames (e.g., die attach), packaging respective die and separating packaged die. In examples, a plurality lead frames are implemented on a sheet of electrically conductive material, and the sheet can be subjected to deformation throughout the handling fabrication process. The deformation that can cause damage to lead frames and reduce the number of acceptable units per lead frame sheet.

### SUMMARY

One example described herein provides an apparatus that includes a lead frame sheet. The sheet includes a plurality of lead frames and a reinforcement feature. A pair of adjacent lead frames includes an arrangement of opposing leads along adjacent edges thereof, in which the opposing leads are spaced apart from and coupled to each other by an elongated dam bar. The dam bar extends longitudinally along the adjacent edges of the adjacent lead frames. The reinforcement feature extends across the dam bar, in which the leads and the reinforcement feature have a thickness, in a direction orthogonal to a surface of the sheet, which is greater than a thickness of the dam bar.

Another example described herein provides a method of making a semiconductor device. The method includes attaching a plurality of die to die pads of respective lead frames of a lead frame sheet. The method also includes electrically coupling a lead of the respective lead frames of the lead frame sheet to a conductive terminal of the respective die. The method also includes encapsulating the plurality of die in a molding material and separating respective packaged semiconductor devices from one another. The separation includes cutting through portions of the molding material, portions of leads and at least one reinforcement feature that extends across a dam bar along a respective saw street. The leads and reinforcement feature(s) can have a thickness, in a direction orthogonal to a surface of the sheet, which is greater than a thickness of the dam bar.

Another example described herein provides a semiconductor device. The semiconductor device includes a lead frame, a semiconductor die and a molding material encapsulating the semiconductor die and a portion of the lead frame. The lead frame includes a die pad, and the semiconductor die is on the die pad. The lead frame also includes a tie bar having proximal and distal end portions. The proximal end portion of the tie bar is coupled to the die pad, and the tie bar extends longitudinally from the proximal end portion towards a corner of the lead frame to terminate in the distal end portion thereof. The lead frame also includes an arrangement of leads spaced apart from and surrounding the die pad along at least two sides of the lead frame. A portion of the tie bar extends between a pair of adjacent leads and has a width that is reduced relative to a width of the proximal end portion of the tie bar.

### BRIEF DESCRIPTION OF THE DRAWINGS

FIG. 1 is a plan view of part of an example lead frame sheet showing lead frames having reinforcement features within saw streets.

FIGS. 2A, 2B and 2C are enlarged views of parts of a lead frame sheet showing reinforcement features across a saw street between lead frames.

FIG. 3 is a plan view of part of a lead frame sheet showing a lead frame having a first die pad configuration.

FIG. 4 is a plan view of part of a lead frame sheet showing a lead frame having a second die pad configuration.

FIG. 5 is an enlarged view of part of an example lead frame sheet showing tie bars and reinforcement features

FIG. 6 is an enlarged view of part of another example lead frame sheet showing tie bars and reinforcement features.

FIG. 7 is a plan view of part of another example lead frame sheet showing lead frames having reinforcement features across saw streets.

FIG. 8 is a plan view of part of a lead frame sheet showing lead frames having multiple types of reinforcement features.

FIG. 9 is an enlarged view of part of an example lead frame sheet of FIG. 8 showing tie bars and reinforcement features.

FIG. 10 is an isometric view showing a bottom view of a portion of a lead frame sheet.

FIG. 11 is an isometric view showing a top view of lead frame sheet portion of FIG. 10.

FIG. 12 is a flow diagram showing an example method of making a semiconductor device.

### DETAILED DESCRIPTION

This description relates generally to lead frames and lead frame sheets for use in making packaged semiconductor devices, such as integrated circuit (IC) packages or system on chip (SOC) packages. As described herein, a lead frame sheet includes reinforcement features that extend across dam bars between adjacent lead frames. As used herein, the dam bar refers to an elongated, sacrificial (e.g., dummy) support structure of the lead frame sheet (e.g., a metal strip) within the saw street between adjacent pairs of individual lead frames.

In one example, the reinforcement features are configured as bridge features. As used, herein a bridge feature refers to a feature on a respective side of a lead frame sheet having side edges that extend across a respective dam bar and are coupled between distal ends of opposing leads of adjacent lead frames. In examples, an arrangement of respective bridge feature are configured to extend across the respective dam bar between distal ends of the opposing leads along opposing sides of adjacent lead frames. For example, the bridge features are formed of the same material as the lead frame sheet.

In another example, the reinforcement features can be configured as ribbon features. As used herein, a ribbon feature refers to an elongated feature on a respective side of the lead frame extending longitudinally along a central portion of a respective dam bar and having side edges spaced apart from distal ends of opposing leads of the adjacent lead frames. A given ribbon feature can have a length that is coextensive with the entire length of the dam bar between an adjacent pair of lead frames. Also, in some examples, ribbon features can be used in combination with the bridge features across one or more dam bars between adjacent lead frames. Alternatively, ribbon features can be used separately from (e.g., in the absence of) bridge features across respective dam bars.

In some examples, reinforcement can also be provided by configuring the lead frames to include a wider tie bar. As used herein, the tie bar refers to an internal support structure of a respective lead frame configured to support a die pad (or paddle) with and the dam bar. For example, the tie bar is configured as a metal strip having a proximal end coupled to the die pad. The tie bar extends from the die pad to terminate in a distal end at or near a corner of the lead frame (after the lead frame sheet is singulated to form individual lead frames), which resides at least partially within the saw street. In the lead frame sheet form, the tie bars of adjacent lead frames are connected to each other. To reduce electromagnetic interference, the tie bar can have a tapered width along an intermediate portion of the tie bar that extends between a pair of leads near the corner of the lead frame.

By implementing one or more of forms of reinforcement features in the lead frame and/or lead frame sheet, as described herein, deformation of respective lead frames can be reduced or eliminated during manufacture and handling of the lead frame sheets. For example, twisting of lead frames that tends to occur during plating process can be reduced. Additionally, the reinforcement features can reduce mold flashing or mold bleed out as well as wire sweep, which tend to occur during encapsulation. As a result of implementing one or more reinforcement features, as described herein, the number of acceptable units can increase for a given lead frame sheet.

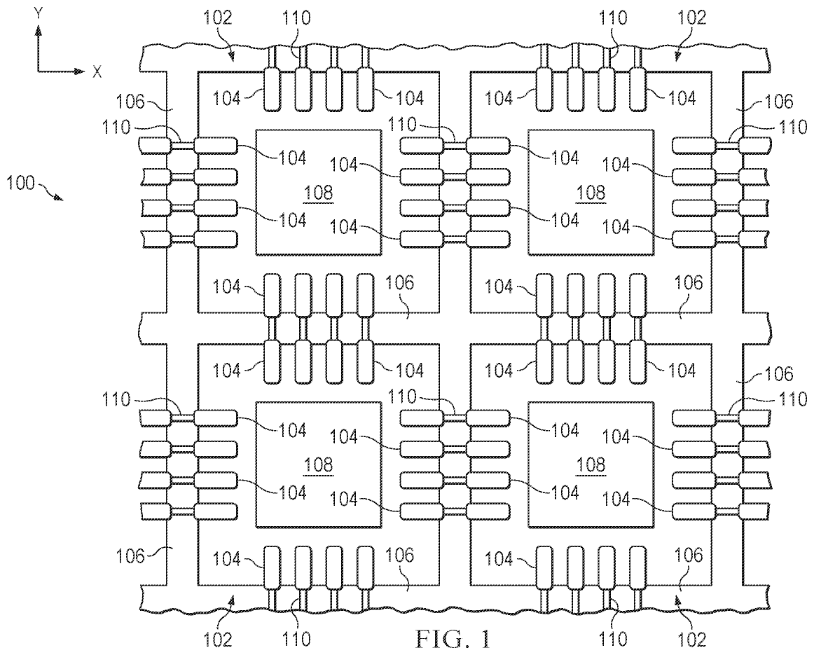

FIG. 1 is a plan view of part of an example a sheet (or a lead frame sheet, or a strip) 100 that includes a plurality of lead frames 102. The sheet 100 can be formed of an electrically conductive material, such as a metal (e.g., copper, aluminum or another metal). In the example of FIG. 1, the lead frames 102 are arranged in rows along a first direction (e.g., an X-direction) and in columns a long a second direction (e.g., a Y-direction). The first and second directions are orthogonal to each other and can define a virtual plane extending through the sheet 100. A thickness of the sheet 100 is along a Z-direction (not shown in FIG. 1), which is orthogonal to the first and second directions (e.g., orthogonal to the X- and Y-directions).

Each lead frame 102 can include an arrangement of leads 104 along one or more edges of the lead frame 102. The number and locations of the leads can vary depending on the type of package being formed. Examples of some types of packages that the lead frames can be used to make include single row packages (e.g., single inline packages), dual row packages (e.g., dual inline packages, flat back packages, small outline integrated circuit packages), quad row packages (e.g., quad flat no leads (QFN) or quad flat package). In the example of FIG. 1, the lead frames 102 include an arrangement of leads 104 along each side of the lead frame 102. The number and distribution of leads 104 on each side can be the same or different for the respective lead frame 102.

Each pair of adjacent lead frames 102 have adjacent edges coupled to each other by a dam bar 106. The dam bars 106 include the sheet material configured (e.g., by etching) to a thickness that is less than a maximum thickness of the sheet 100. The adjacent edges of the adjacent lead frames include opposing leads 104 that extend from a respective lead frame 102 to terminate in respective distal ends. Each dam bar 106 and distal end portions of the respective leads are located in a saw street, along which the lead frame sheet is cut during a package separation or singulation process. The dam bars 106 and saw streets thus extend along both the first and second directions (e.g., the X- and Y-directions). In the example of FIG. 1, the distal ends of the leads 104 extend into the dam bar 106, and the distal ends of the opposing leads are spaced apart from each other by a distance extending across a portion of the dam bar.

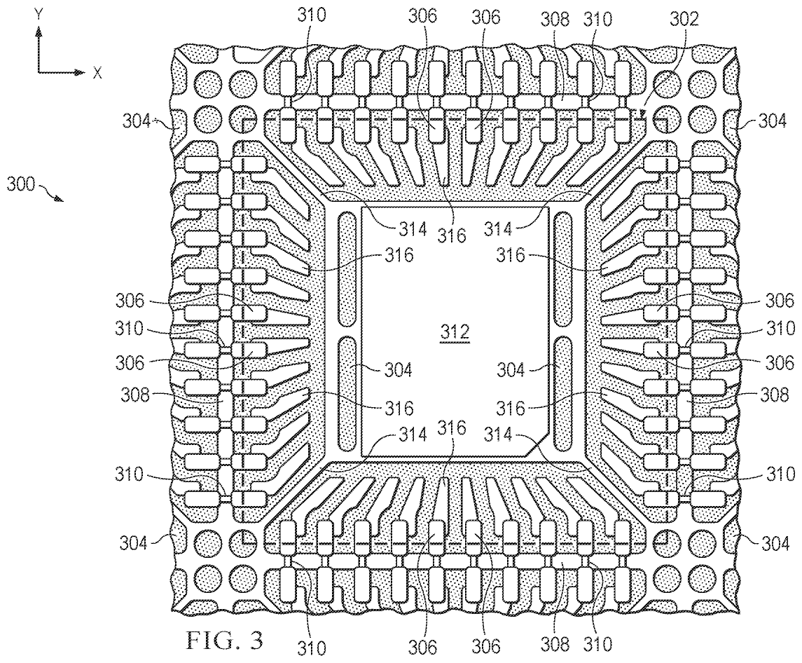

Each lead frame 102 also includes a die pad (also referred to as a die attach pad) 108. In the example of FIG. 1, the die pads 108 are located in a central portion of the respective lead frames. The die pads 108 include a planar surface configured to receive one or more semiconductor die, such as during a die attach process. The die pads 108 can be supported in the sheet 100 by tie bars (not shown in FIG. 1, but see, e.g., FIGS. 3-6 and 8-9). The tie bars are configured to join and hold the lead frames 102 and respective components thereof together in a unitary structure that forms the sheet 100. In some example, the die pads 108 are supported relative to the sheet 100 using an adhesive carrier or tape (not shown) during portions of the manufacturing process.

The sheet 100 also includes reinforcement features 110 extending across the dam bars 106. In the example of FIG. 1, the reinforcement features 110 include bridge features configured to extend across the dam bar 106 between respective pairs of the opposing leads 104 along adjacent edges of adjacent lead frames. For example, the bridge features 110 extend in a direction that is orthogonal to the direction that the dam bar 106 extends across the sheet 100. Thus, if a respective dam bar 106 extends in the Y-direction, then the bridge features 110 extend in the X-direction across the respective dam bar. Conversely, if a respective dam bar 106 extends in the X-direction, then the bridge features 110 extend in the Y-direction across the respective dam bar. The sheet 100 has an increased thickness at the reinforcement features 110 and leads 104 (e.g., a full or maximum sheet thickness) compared to the other parts including the dam bar 106. The increased thickness at the bridge features is thus configured to provide structural support to resist deformation of the sheet 100.

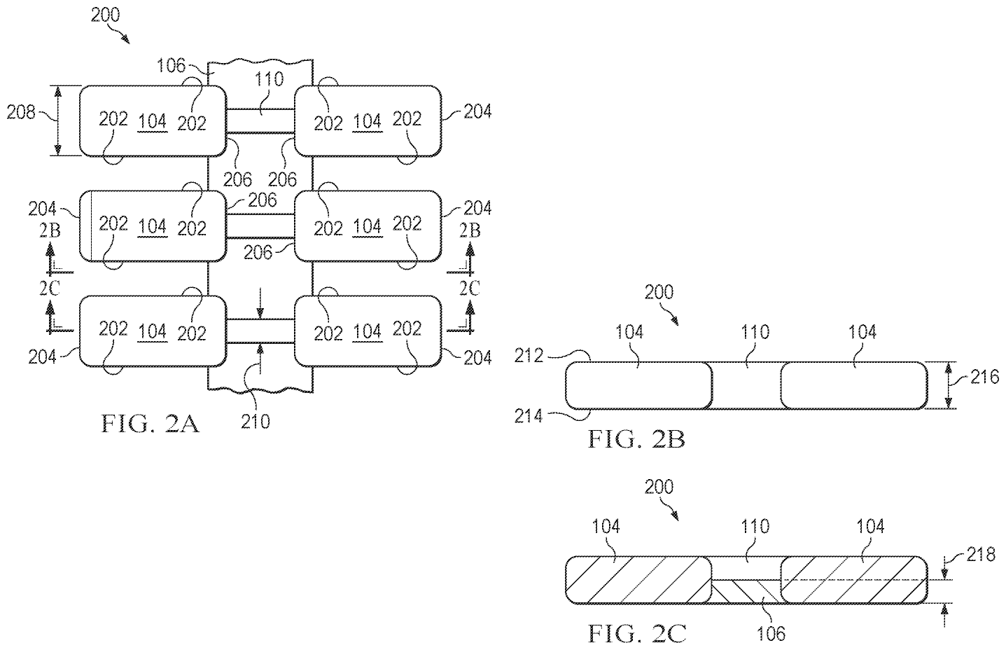

FIGS. 2A, 2B and 2C depict a portion 200 of the sheet 100 showing an enlarged view of the leads 104 and reinforcement features 110. FIGS. 2B and 2C are cross sectional view of FIG. 2A taken along respective cross-section lines. As shown in FIG. 2A, each of the leads 104 has side edges 202 that extend longitudinally between proximal and distal ends 204 and 206. Each of the bridge features 110 is coupled to and extends from the distal ends 206 of a respective pair of the opposing leads. Each lead 104 has a width, shown at 208, representative of the distance between the side edges 202 of the respective lead. Similarly, each bridge feature 110 has a width, shown at 210, representative of the distance between the edges of the respective bridge feature. For example, the width 210 of each bridge feature 110 is less than or equal to about one-half (e.g., in a range from about one-third to about one-half) the width 208 of the respective opposing leads 104 between which the respective bridge extends.

As shown in FIGS. 2B and 2C, the sheet 100 has first and second surfaces 212 and 214. A distance between the surfaces 212 and 214 (e.g., in a direction orthogonal to the surfaces 212 and 214 of the sheet) at any location across the sheet 100 defines a thickness of the sheet at such location. As shown in FIG. 2B, each of the leads 104 and bridge features 110 has a thickness 216, which can be the same thickness. In an example, the thickness 216 of the leads 104 and bridge features 110 can be representative of a full (or maximum) thickness of the sheet 100. FIG. 2C is a cross-sectional view taken through the sheet portion 200 through the dam bar 106 spaced apart from the leads 104. FIG. 2C shows a thickness 218 of the dam bar 106. The thickness 218 of the dam bar 106 is less than the thickness 216 of the leads 104 and bridge features 110. As an example, the thickness 218 of the dam bar 106 is about one-half or less than the thickness 216 of the leads 104 and bridge features 110. Other values of relative thicknesses 216 and 218 can be used in other examples.

As a further one example, the sheet 100 is created using a starting sheet or strip of a metal (e.g., copper, aluminum or other metal) having first and second side surfaces 212 and 214, and the various features of the metal structure are stamped or patterned using a punch press or cutting to form the leads 104, die pads 108 and tie bars (not shown). A subsequent masked etch process is used to form features having different thicknesses. For example, half-etching process can be implemented to form thinner features (e.g., the dam bar 106) and thicker features (e.g., leads 104 and reinforcement features 110) can be formed by masking such areas during the etching process.

FIG. 3 is a plan view of part of a lead frame sheet 300 that includes a lead frame 302. The example of FIG. 3 shows the lead frame sheet 300 after die attach and encapsulation with a molding material 304 and before separation. The molding material 304 (shown as solid dark portions) is visible through openings of the sheet 300. For molding material can be a plastic or epoxy material. The lead frame sheet 300 can be formed to provide an arrangement of lead frames distributed across the sheet, such as described herein. The lead frame 302 includes an arrangement of leads 306 along edges of the lead frame. As shown in FIG. 3, dam bars 308 extend along respective edges of the lead frame 302 between the lead frame and each adjacent lead frame. As described herein, the dam bars 308 are configured (e.g., by etching) to have a thickness that is less than a maximum thickness of the sheet 300. Each of the leads 306 can have thickness that is greater than the thickness of the dam bars 308, such as the maximum thickness of the sheet. Each of the leads 306 of the lead frame 302 can extend into a saw street and be coupled to a respective dam bar 308. Thus, the dam bars 308 are configured to support the leads across the sheet 300. In the example of FIG. 3, each of the leads 306 extends in a direction (the X- or Y direction) that is orthogonal to a longitudinal direction (the Y- or X-direction) that the dam bars 308 extend.

The sheet 300 also includes reinforcement features 310 extending across the dam bars 106. In the example of FIG. 3, the reinforcement features 310 are implemented as bridge features configured to extend across the dam bar 308 between respective pairs of the opposing leads 306 along adjacent edges of adjacent lead frames. For example, the bridge features 310 extend in a direction that is orthogonal to the direction that the dam bar 308 extends across the sheet 100. Thus, if a respective dam bar 308 extends in the Y-direction, then the bridge features 310 crossing the respective dam bar extend in the X-direction. Conversely, if a respective dam bar 308 extends in the X-direction, then the bridge features 310 crossing the respective dam bar extend in the Y-direction.

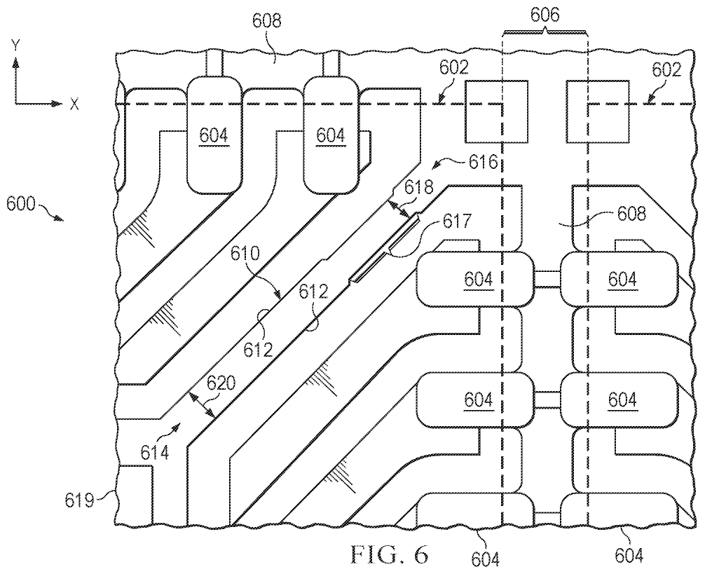

The lead frame 302 also includes a die pad 312. The die pad 312 can be located in a central portion of the lead frame 302. The die pad 312 includes a planar surface (the side surface opposite the surface shown in FIG. 3) configured to support one or more semiconductor die. The die pad 312 can have thickness that is greater than the thickness of the dam bar 308 or other half-etched features, such as at a maximum sheet thickness. The die pad 312 is supported in the sheet 300 by an arrangement of tie bars 314. The tie bars 314 are configured to join and hold the lead frame 302 and respective components thereof together in a unitary structure within a plane of the sheet 300. For example, the tie bar 314 has a first end portion coupled to a die pad 312 (e.g., at or near a respective corner thereof) and extends from the die pad to terminate at a corner support feature of the lead frame 302. A respective tie bar 314 can thus be provided at each corner of lead frame. In some examples, the width of tie bar can vary along its length (see, e.g., FIG. 6).

In the example of FIG. 3, the lead frame 302 also includes cantilever lead features 316. The cantilever lead features 316 extend from respective leads 306 toward the die pad 312. The cantilever lead features 316 can provide lead bonding structure closer to the die pad 312, which is spaced apart inwardly relative to the leads 306. The lead features 316 can provide bond locations for making electrical connections between terminals of the die and the respective leads 306 (e.g., using bond wires).

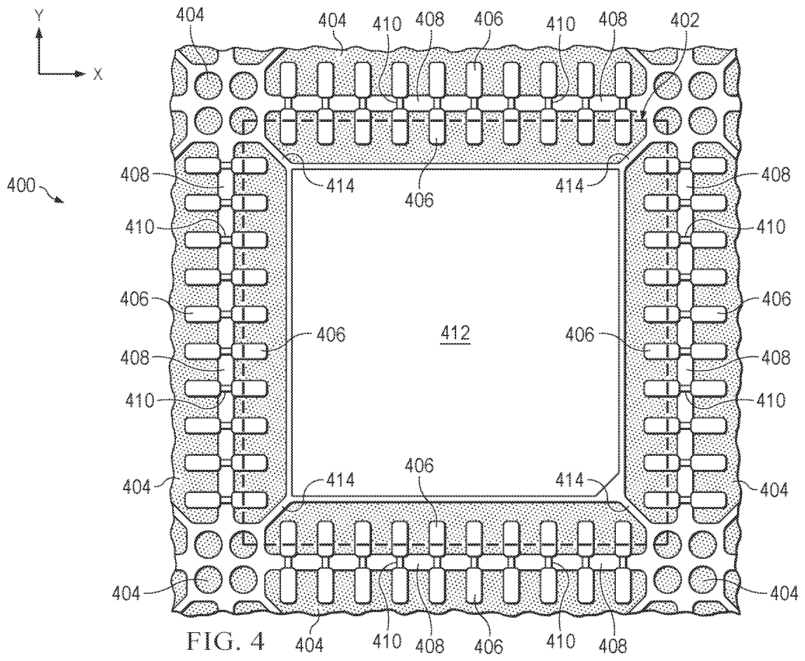

FIG. 4 is a plan view of part of another configuration of lead frame sheet 400 showing a lead frame 402. Similar to FIG. 3, the sheet 400 is at an intermediate fabrication stage, after die attach and before separation. The individual die have also been encapsulated with a molding compound 404, which is visible (as dark areas) through openings of the sheet 400. As described herein, the lead frame sheet 400 can be formed to provide an arrangement of lead frames distributed across the sheet, each including an arrangement of leads 406 along edges of the respective lead frames.

Dam bars 408 also extend longitudinally along respective edges of the lead frame 402 between the lead frame and each adjacent lead frame. Each of the leads 406 can have thickness that is greater than the thickness of the dam bars 408, such as the maximum thickness of the sheet. Each of the leads 406 of the lead frame 402 can extend into a saw street and be coupled to a respective dam bar 408. As described herein, the dam bars 408 are configured (e.g., by etching) to have a thickness that is less than a maximum thickness of the sheet 400. The dam bars 408 are configured to support the leads 406 across the sheet 400.

The sheet 400 also includes reinforcement features 410 extending across the dam bars 106. In the example of FIG. 4, the reinforcement features 410 are implemented as bridge features configured to extend across the dam bar 408 between respective pairs of the opposing leads 406 along adjacent edges of adjacent lead frames. For example, the bridge features 410 extend in a direction that is orthogonal to the direction that the dam bar 408 extends across the sheet 100. Thus, if a respective dam bar 408 extends in the Y-direction, then the bridge features 410 crossing the respective dam bar extend in the X-direction. Conversely, if a respective dam bar 408 extends in the X-direction, then the bridge features 410 crossing the respective dam bar extend in the Y-direction.

The lead frame 402 also includes a die pad 412. The die pad 412 can be located in a central portion of the lead frame 402. The die pad 412 includes a planar surface (the side surface opposite the surface shown in FIG. 4) configured to support one or more semiconductor die. The die pad 412 can have thickness that is greater than the thickness of the dam bar 408 or other half-etched features, such as at a maximum sheet thickness. The die pad 412 is supported in the sheet 400 by an arrangement of tie bars 414. The tie bars 414 are configured to join and hold the lead frame 402 and respective components thereof together in a unitary structure within a plane of the sheet 400. For example, the tie bar 414 has a first end portion coupled to a die pad 412 (e.g., at or near a respective corner thereof) and extends from the die pad to terminate at a corner support feature of the lead frame 402. A respective tie bar 414 can thus be provided at each corner of lead frame. In some examples, the width of tie bar can vary along its length (see, e.g., FIG. 6). In the example of FIG. 4, the die pad 412 occupies a relatively larger area of the lead frame 402 than the example of FIG. 3. As a result, side edges of the die pad 412 are closer to the leads 406 of the lead frame 402 than in the configuration of FIG. 3, and cantilever lead features are not included for making electrical connections between the leads and the terminals of the die.

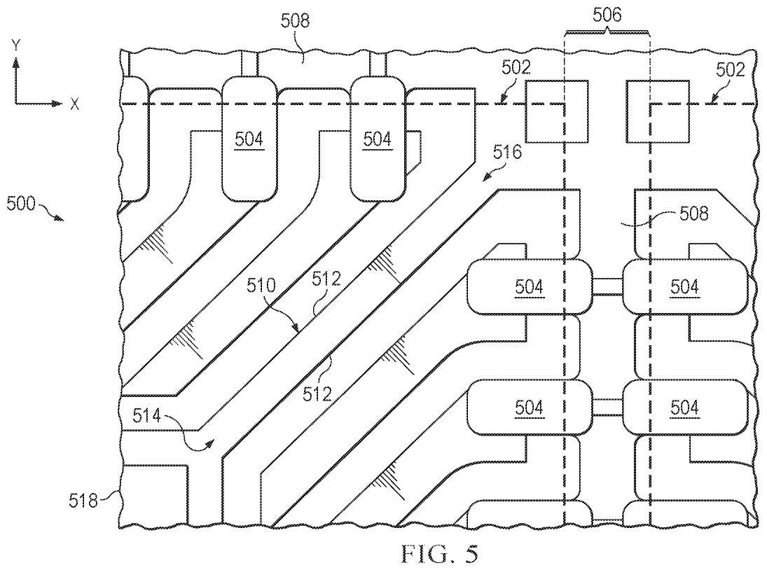

FIGS. 5 and 6 depict an enlarged view of part respective lead frame sheets 500 and 600 having different tie bar configurations. The lead frame sheet 500 can have a configuration similar to the example of FIG. 3. For example, the sheet 500 includes portions of two lead frames 502 that includes respective arrangements of leads 504. Space between respective edges of the lead frames 502 defines a saw street 506. A dam bar 508 extends longitudinally along a central portion of the saw street 506. A tie bar 510 has spaced apart side edges 512 that extend between proximal and distal ends 514 and 516, respectively. The proximal end 514 is coupled to a die pad 518, and the distal end 516 is coupled to orthogonally extending dam bars 508 near a respective corner of the lead frame 502. In the example of FIG. 5, a width of the tie bar 510 (e.g., the distance between side edges 512) remains constant along its length between ends 514 and 516.

The example lead frame sheet 600 in FIG. 6 is similar to the sheet 500 of FIG. 5, except the sheet 600 has a different tie bar configuration. For example, the sheet 600 includes portions of two lead frames 602 that includes respective arrangements of leads 604. Space between respective edges of the lead frames 602 also defines a saw street 606, along which a dam bar 608 extends. The lead frame 602 includes a tie bar 610 having spaced apart side edges 612 that extend between proximal and distal end portions 614 and 616, respectively. The distal end portion 616 of the tie bar 610 includes a region 617 that extends between a pair of adjacent (e.g., corner-most) leads 604 of the lead frame 602. The region 617 of the tie bar 610 has a first width, shown at 618. The proximal end portion 614 of the tie bar 610, which is coupled to a die pad 619, has a second width, shown at 620. As shown in the example of FIG. 6, the second width 620 is greater than the first width 618. The increased width 620 along at least a portion of the tie bar 610 configures the tie bar as a reinforcement feature for the lead frame 602 and helps reduce deformation of the lead frame. In some examples, the distal-most portion of the tie bar 610, which is located between the region 617 and the distal end 616 of the tie bar, also has the increased width 620.

As a further example, the reduced width 618 in the region 617 reduces electromagnetic interference (EMI) between the tie bar 610 and the adjacent leads 604 on the cantilevered lead frame 602. For example, the reduced width of the region 617 is configured to maintain a minimum spacing between metal components, namely a minimum spacing between the adjacent lead 604 and the tie bar 601 (e.g., about 0.15 mm). If the spacing between the tie bar and lead fall below the minimum of metal-to-metal spacing, such spacing could cause disturbance degrading the resulting circuit's performance or, in some cases, even prevent the IC from functioning altogether. As an example, metal lines and metal interconnects are essential for more communicating reliable, high speed data, but also can contribute significantly to inducing EMI. With the reduced area of ICs and metal interconnects (e.g., metal-to-metal spacing) on lead frames, ICs becomes even more vulnerable to EMI. By reducing the width of the tie bar in the region 617, as described herein, the lead frame 602 complies with the minimum spacing, and the tie bar 610 is configured to help radiate the EMI without degrading performance of the IC.

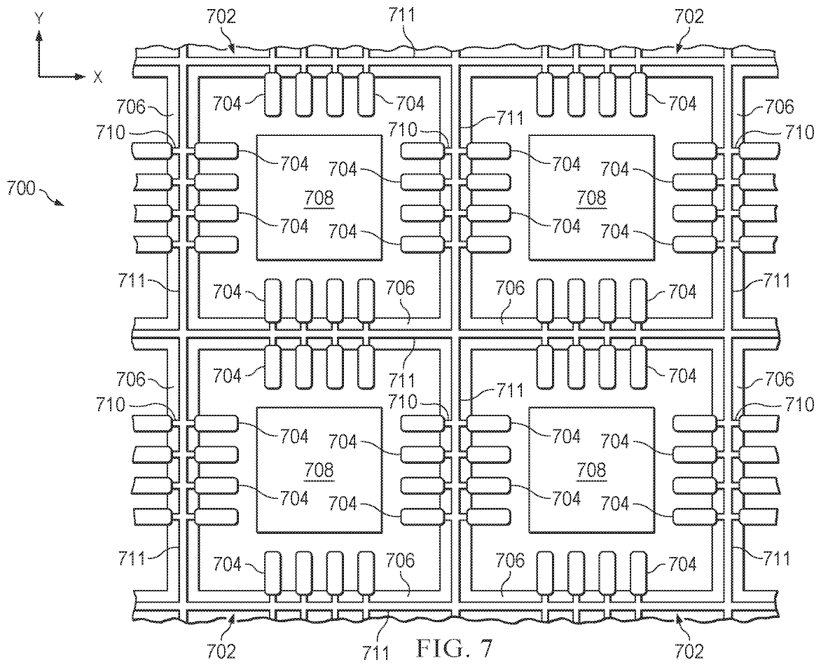

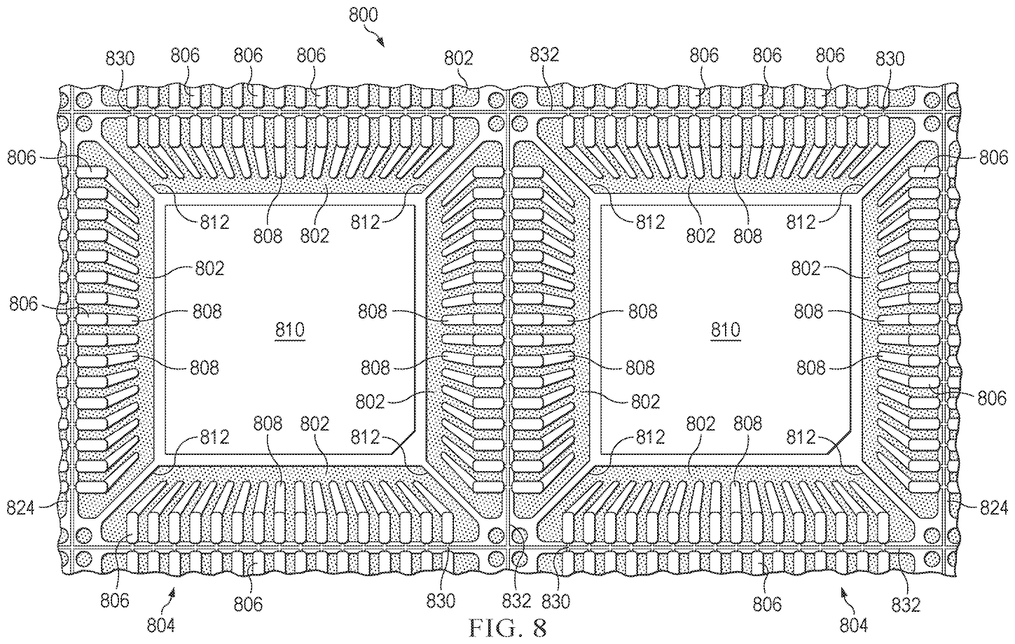

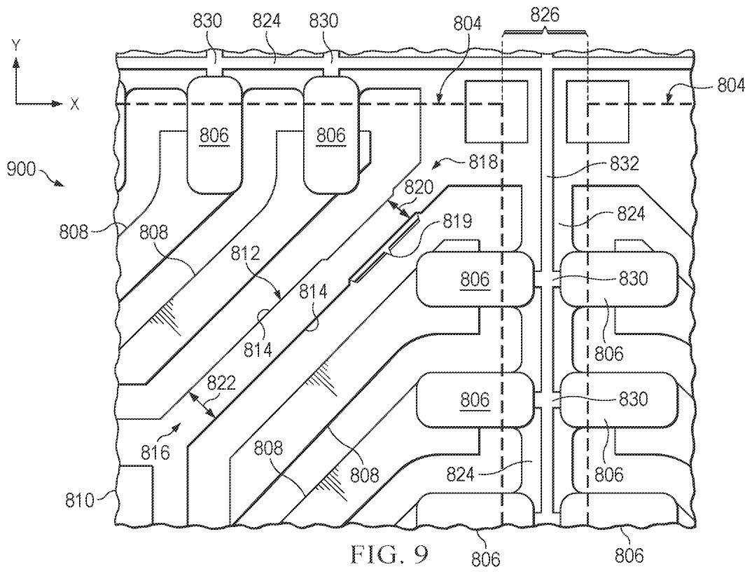

FIG. 7 is a plan view of part of another example lead frame sheet 700 includes a plurality of lead frames 702. In the example of FIG. 7, the lead frames 702 are arranged in rows along a first direction (e.g., an X-direction) and in columns a long a second direction (e.g., a Y-direction), as described herein. Each lead frame 702 can include an arrangement of leads 704 along one or more edges of the respective lead frame. Each pair of adjacent lead frames 702 have adjacent edges coupled to each other by a dam bar 706, which include the sheet material configured (e.g., by etching) to a thickness that is less than a maximum thickness of the sheet 700. The adjacent edges of the adjacent lead frames include opposing leads 704 that extend from a respective lead frame 702 to terminate in respective distal ends that are spaced apart and facing each other along a respective dam bar 706. Each dam bar 706 and distal end portions of the respective leads are located in a saw street. Each lead frame 702 also includes a die pad 708 located at a central portion of the respective lead frame. The die pads 708 can be supported in the sheet 700 by tie bars such as shown in FIGS. 8-9.

The sheet 700 also includes reinforcement features extending across the dam bars 706. The reinforcement features include bridge features 710 configured to extend across the dam bar 706 between respective pairs of the opposing leads 704, such as described herein. In the example of FIG. 7, the reinforcement features also include ribbon features 711 extending longitudinally along a central portion of the dam bar. For example, the ribbon features 711 have side edges spaced apart from distal ends of the opposing leads 704. Each of the bridge features 710 and ribbon features 711 have a thickness (e.g., in Z-direction) orthogonal to a virtual plane extending in the X- and Y-directions, which is greater than a thickness of the dam bars 706.

For example, the bridge features 710 extend in a direction that is orthogonal to the direction that a respective dam bar 706 extends across the sheet 700, whereas the ribbon features 711 extend along the same direction as the respective dam bar. Thus, if a respective dam bar 706 extends in the Y-direction, then the bridge features 710 extend in the X-direction across the respective dam bar and the ribbon features 711 extend in the Y-direction. Conversely, if a respective dam bar 706 extends in the X-direction, then the bridge features 710 extend in the Y-direction and the ribbon features 711 extend in the X-direction across the respective dam bar. The lead frame sheet 700 has an increased thickness at the reinforcement features 710, 711 and at leads 704 (e.g., a full or maximum sheet thickness) compared to the other parts of the sheet, including the dam bar 706. The increased thickness at the bridge features 710 and ribbon features 711 configures the sheet 700 with additional structural support to resist deformation.

FIG. 8 depicts another example of a lead frame sheet 800, which includes multiple types of reinforcement features to reduce deformation of the sheet. The example of FIG. 8 shows the lead frame sheet 800 at an intermediate processing stage after die attach and encapsulation with a molding compound 802 but before package separation. The molding compound 802 (shown as solid dark portions) is visible through openings of the sheet 800. The sheet 800 includes an arrangement of lead frames 804 distributed across the sheet, such as described herein. The portion of the sheet shown in FIG. 8 includes two lead frames 804. As described herein, each of the lead frames 804 includes an arrangement of leads 806 along edges of the respective lead frame. In the example of FIG. 8, the lead frames 804 also includes cantilever lead features 808. The cantilever lead features 808 extend from respective leads 806 inwardly and angled toward a die pad 810, which located in a central portion of the lead frame 804. The cantilever lead features 808 provide bonding structures closer to the die 810 for making electrical connections between terminals of the die and the respective leads 806 (e.g., using bond wires).

Each die pad 810 is supported in the sheet 800 by an arrangement of respective tie bars 812. The tie bars 812 are configured to join and hold the lead frame 804 and respective components thereof together in a unitary structure within the sheet 300. For example, the tie bars are coupled between the die pad and respective corners of lead frame. With reference to FIG. 9, which shows an enlarged view of part of sheet 800 of FIG. 8 without the encapsulation, each tie bar 812 has spaced apart side edges 814 that extend between proximal and distal end portions 816 and 818, respectively. The white solid features throughout the sheet represent openings extending through the sheet, which are shown filled with molding compound 802 in FIG. 8.

A region 819 of the distal end portion 818 of the tie bar 812 is located between a pair of adjacent leads 806 and has a first width, shown at 820. The proximal end portion 816 of the tie bar 812 has a second width, shown at 822. As shown in the example of FIG. 9, the second width 822 is greater than the first width 820 along the region 819. The increased width, shown at 822 along at least a portion of the tie bar 812 helps reduce deformation of the lead frame 804. The reduced width 820 in the region 819 helps reduce interference between the tie bar 812 and the adjacent leads 806.

The distal ends of the respective tie bars 812 are coupled to respective dam bars 824 that surround the lead frames within respective saw streets 826 of the sheet 800. The distal ends of the respective tie bars 812 are coupled respective dam bars 824. The distal-most portion of the tie bar 812, which is located between the region 818 and the dam bar 824 the region 818 having the reduced width, can also be configured with the increased width 822.

With reference to both FIGS. 8 and 9, the sheet 800 also includes reinforcement features extending across the dam bars 824. The reinforcement features include bridge features 830 and ribbon features 832. The bridge features 830 are configured to extend across the dam bar 824 between respective pairs of the opposing leads 806, such as described herein. The ribbon features 832 extend longitudinally along a central portion of the dam bar 824 in the same direction that the dam bar extends across the sheet 800. For example, the bridge features 830 extend in a direction orthogonal to the ribbon feature 832 and intersect with each other (e.g., are coupled together) within a given saw street 826. The ribbon features 832 have side edges spaced apart from distal ends of the opposing leads 806.

Each of the leads 806, the bridge features 830 and ribbon features 832 can have a thickness (e.g., in Z-direction) orthogonal to a virtual plane extending in the X- and Y-directions, which is greater than a thickness of the dam bars 824, the tie bars 812 and lead features 808. For example, the leads 806, the bridge features 830 and ribbon features 832 retain a full thickness of the sheet 800, and other features of the sheet, including the dam bars 824, the tie bars 812 and lead features 808, have reduced thickness by etching.

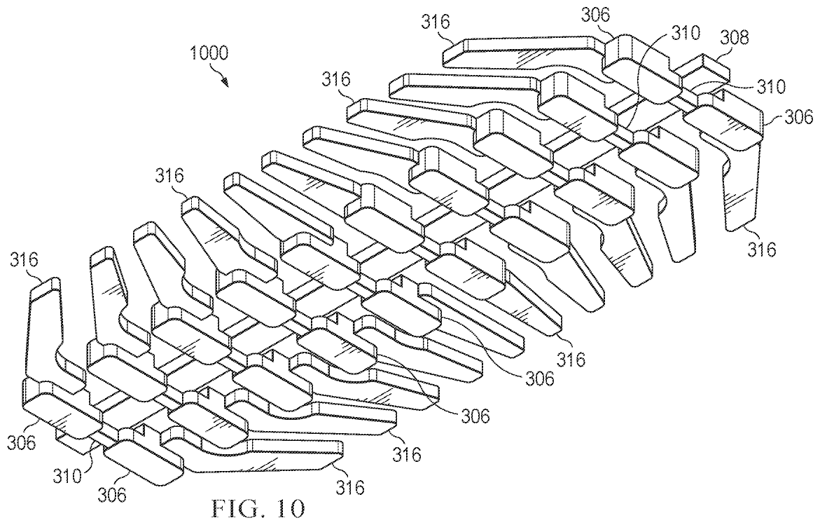

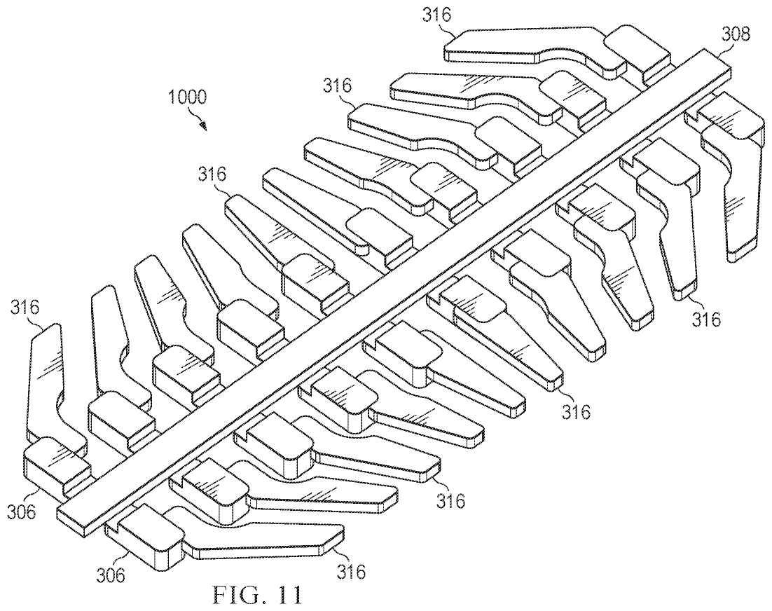

As a further example, FIGS. 10 and 11 are isometric views 1000 and 1100 from opposite sides of a portion of the lead frame sheet 300 of FIG. 3. Specifically, FIGS. 10 and 11 show bottom and top views, respectively, of the portion of the sheet 300 between cantilever lead features 316 for a pair of adjacent lead frames 302 without the molding material 304 having been applied. As shown, the opposing set if lead features for the adjacent lead frames include leads 306 and respective lead features, as well as a dam bar 308 extending along the respective edges of the lead frames. Bridge features 310 extend between each opposing pair of leads 306.

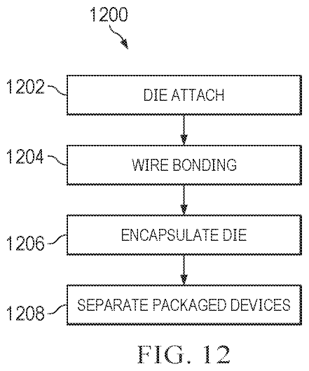

In view of the foregoing structural and functional features described above, a method that can be implemented to make a semiconductor device is shown in FIG. 12. While, for purposes of simplicity of explanation, the method of FIG. 12 is shown and described as executing serially, the method not limited by the illustrated order, as some actions could occur in different orders, multiple times and/or concurrently from that described herein.

The method 1200 begins at 1202 by performing a die attach process. For example, a die has been separated or singulated from a wafer on which integrated circuitry has been formed. The die has a top side with conductive terminals (e.g., copper bond pads) for electrical coupling to respective leads of the lead frame. The bottom side of the die is placed on and mounted to a surface of a die pad of a lead frame, such as using pick and place equipment, and the die terminals remain exposed. The die attachment at 1202 can be performed using an adhesive attachment material or soldering. In the die attach at 1202, multiple dies can be attached to corresponding die attach pads, and other circuit components can be similarly attached to corresponding die pads. The lead frame on to which the die is placed can be one of an arrangement of lead frames distributed across a lead frame sheet, which is configured according any of the examples described herein (e.g., FIGS. 1-11). Thus, the lead frame sheet and/or lead frame itself includes one or more reinforcement features. For example, the reinforcement features can include bridge features, ribbon features and/or tie bar reinforcement features, as described herein.

At 1204, the method includes performing wire bonding. For example, one or more die undergo an electrical connection process to electrically couple leads of respective lead frame(s) to respective terminals of the die(s), such as by using bond wires. The bond wires, each include a first end connected (e.g., soldered or ultrasonically welded) to a corresponding conductive terminal of the die, and a second end connected (e.g., soldered or ultrasonically welded) to the lead. In another example, the electrical connection processing at 1204 includes flip-chip die attach techniques to electrically couple given respective terminals of the die to respective leads, alone or in combination with wire bonding.

At 1206, the method includes encapsulating the one or more die. For example, the encapsulation at 1206 includes enclosing the one or more die, the die pad(s), bond wires and portions of the leads and the dam bars a molded package structure, such as using a mold having one or more cavities. In an example, the encapsulation at 1206 forms a single molded structure of an insulating materials (e.g., plastic or epoxy) that covers and encloses a plurality of die, bond wires and other interconnections across the top surface of the lead frame sheet. In another example, the encapsulation at 1206 creates a single molded structure for each row or for each column of device portions.

At 1208, the method 1200 includes separating (or singulating) packaged semiconductor devices. The package separation at 1208 separates individual packaged semiconductor devices from one another. For example, the package separation process uses a rotating cutting saw blade that is configured to cut through the saw streets along respective X-direction and another process to translate the saw blade along the Y-direction. The first saw cutting process cuts through portions of the package structure, dam bars, reinforcement features and portions of the leads located within the saw streets of the lead frame sheets between respective lead frames. Thus, example lead frame sheets that include bridge and/or ribbon reinforcement features are removed from the respective semiconductor devices during the package separation at 1208. In some examples, the resulting packaged electronic device can be a QFN device.

In this description, the term “couple” or “couples” means either an indirect or direct connection. Thus, if a first device couples to a second device, that connection may be through a direct connection or through an indirect connection via other devices and connections. For example, if device A generates a signal to control device B to perform an action, then: (a) in a first example, device A is coupled to device B; or (b) in a second example, device A is coupled to device B through intervening component C if intervening component C does not alter the functional relationship between device A and device B, so device B is controlled by device A via the control signal generated by device A.

Also, in this description, a device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof. Furthermore, a circuit or device described herein as including certain components may instead be configured to couple to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor wafer and/or integrated circuit (IC) package) and may be configured to couple to at least some of the passive elements and/or the sources to form the described structure, either at a time of manufacture or after a time of manufacture, such as by an end user and/or a third party.

The recitation “based on” means “based at least in part on.” Therefore, if X is based on Y, X may be a function of Y and any number of other factors.

Modifications are possible in the described embodiments, and other embodiments are possible, within the scope of the claims.

What is claimed is:

1. A method of making a semiconductor device, comprising:
attaching a plurality of die to die pads of respective lead frames of a lead frame sheet;
electrically coupling a lead of the respective lead frames of the lead frame sheet to a conductive terminal of the respective die;
covering portions of the plurality of die and portions of the lead frame sheet in a molding material; and
separating respective packaged semiconductor devices from one another, in which the separating includes cutting through portions of the molding material, portions of leads and at least one reinforcement feature that extends across a dam bar along a respective saw street, the leads and the at least one reinforcement feature having a thickness, in a direction orthogonal to a surface of the sheet, which is greater than a thickness of the dam bar.

2. The method of claim 1, wherein the at least one reinforcement feature comprises a ribbon extending longitudinally along a central portion of the dam bar within the saw street, and the separating includes cutting longitudinally through the ribbon.

3. The method of claim 2, wherein the ribbon has side edges spaced apart from distal ends of the opposing leads, which also reside within the saw street.

4. The method of claim 2, wherein the at least one reinforcement feature also includes an arrangement of bridge features, each of the bridge features extending across the dam bar and the ribbon between a respective pair of opposing leads along adjacent edges of adjacent lead frames on the sheet, and the separating includes cutting through the bridge features.

5. The method of claim 1, a particular lead frame of the sheet includes tie bars having proximal and distal end portions, the tie bars extending longitudinally from the proximal end portion, which is coupled to a die pad of the particular lead frame, towards a respective corner of the particular lead frame, in which a portion of a respective one of the tie bars located between a pair of the leads near the corner of the particular lead frame has a reduced width relative to a width of the proximal end portion of the respective tie bar.

6. The method of claim 1, wherein the at least one reinforcement feature includes an arrangement of bridge features, in which each of the bridge features extends across the dam bar and is coupled between a respective pair of the opposing leads along adjacent edges of adjacent lead frames, and the separating includes cutting through the bridge features.

7. A semiconductor device, comprising:
a lead frame including:
a die pad;
a tie bar having proximal and distal end portions, the proximal end portion is coupled to the die pad, and the tie bar extends longitudinally from the proximal end portion towards a corner of the lead frame; and
an arrangement of leads spaced apart from and surrounding the die pad along at least two sides of the lead frame, in which a portion of the tie bar that extends between a pair of adjacent leads has a width that is reduced relative to a width of the proximal end portion of the tie bar;
a semiconductor die on the die pad; and
a molding material encapsulating the semiconductor die and a portion the lead frame.

8. The semiconductor device of claim 7, wherein the tie bar of the lead frame includes a plurality of tie bars having proximal end portions coupled to the die pad, in which each of the tie bars has a portion, which extends between a pair of leads near a respective corner of the lead frame, that has a width that is less than a width of the proximal end portion.

9. The semiconductor device of claim 7 including a quad flat no lead package.

10. An apparatus comprising:
a lead frame sheet including:
a plurality of lead frames, a pair of adjacent lead frames including an arrangement of opposing leads along adjacent edges thereof, in which the opposing leads are spaced apart from and coupled to each other by a dam bar, and the dam bar extends longitudinally along the adjacent edges of the adjacent lead frames; and
a reinforcement feature extending across the dam bar, in which the leads and the reinforcement feature have a thickness, in a direction orthogonal to a surface of the sheet, which is greater than a thickness of the dam bar.

11. The apparatus of claim 10, wherein the reinforcement feature includes a bridge feature extending across the dam bar and coupled between at least one pair of the opposing leads along the adjacent edges.

12. The apparatus of claim 11, wherein the reinforcement feature includes an arrangement of bridge features, in which each of the bridge features extend across the dam bar and are coupled between a respective pair of the opposing leads.

13. The apparatus of claim 12, wherein each of the opposing leads along the adjacent edges has sides extending longitudinally between proximal and distal ends thereof, and each of the bridge features is coupled to the distal ends of the respective pair of the opposing leads.

14. The apparatus of claim 13, wherein a distance between the sides of each of the opposing leads defines a lead width, and each of the bridge features has a width between sides thereof that is less than the lead width of the respective pair of opposing leads between which each respective bridge feature extends.

15. The apparatus of claim 14, wherein the width of each bridge feature is less than or equal to about one-half the lead width of the respective opposing leads between which the respective bridge feature extends.

16. The apparatus of claim 10, wherein the reinforcement feature comprises a ribbon extending longitudinally along a central portion of the dam bar.

17. The apparatus of claim 16, wherein the ribbon has side edges spaced apart from distal ends of the opposing leads.

18. The apparatus of claim 16, wherein the reinforcement feature also includes an arrangement of bridge features, each of the bridge features extending across the dam bar and the ribbon between a respective pair of the opposing leads.

19. The apparatus claim 10, wherein a particular lead frame of the sheet includes a tie bar having proximal and distal end portions, the tie bar extending longitudinally from the proximal end portion, which is located inwardly from edges of the particular lead frame, towards a corner of the particular lead frame, in which a portion of the tie bar located between a pair of the leads of the particular lead frame has a reduced width relative to a width of the proximal end portion.

20. The apparatus claim 19, wherein the proximal end portion of the tie bar is coupled to a die pad at a central portion of the particular lead frame, and distal end portion is coupled to at least one respective dam bars near a corner of the particular lead frame.
